(19) United States
(12) Patent Application Publication
(10) Pub. No.: US 2024/0203806 A1
(43) Pub. Date: Jun. 20, 2024

(54) GLASS LAYER WITH LITHO DEFINED THROUGH-GLASS VIA

(71) Applicant: Intel Corporation, Santa Clara, CA (US)

(72) Inventors: Bohan Shan, Chandler, AZ (US); Bai Nie, Chandler, AZ (US); Leonel R. Arana, Phoenix, AZ (US); Dingying XU, Chandler, AZ (US); Srinivas Venkata Ramanuja Pietambaram, Chandler, AZ (US); Hongxia Feng, Chandler, AZ (US); Gang Duan, Chandler, AZ (US); Xiaoying Guo, Chandler, AZ (US); Jeremy D. Ecton, Gilbert, AZ (US); Haobo Chen, Chandler, AZ (US); Bin Mu, Tempe, AZ (US)

(21) Appl. No.: 18/085,291

(22) Filed: Dec. 20, 2022

(51) Int. Cl. H01L 23/15; C03C 17/00; C03C 17/06; H01L 21/48; H01L 23/498

(52) U.S. Cl. CPC H01L 23/15; C03C 17/004; C03C 17/06; H01L 21/486; H01L 23/49822; H01L 23/49827; C03C 2217/253; C03C 2218/365

(57) ABSTRACT

An electronic device, including layers, formed from a material that can remain substantially constant in structure, such as glass. The layer can be preformed with through glass vias that support at least one electrically conductive interconnect. The through glass via can have an edge region that can be substantially coplanar with an exposed surface of the layer.

### TECHNICAL FIELD

This document pertains generally, but not by way of limitation, to glass layers with at least one through-hole, or through-glass via (TGV), configured for use computer chips or similar electronic components.

### BACKGROUND

Computer chips, and other similar components for electronic systems are formed from layers of materials which are usually stacked or placed one on top of the other. The complexity of computer chips and other similar components necessitates minimal displacement of layers or component on layers, or deformation during assembly. Materials which have thermal and mechanical stable properties are usually selected to form the substrate. Silicon is the most commonly used material for a chip or the substrate, but other materials such as glass, plastic or other metals are known in the industry as being suitable for the substrate as well.

A composite of glass fiber cloth and organic resin is most commonly used material for a core of an electrical system, such as a chip. The core is known to be the innermost layer or the center layer of the substrate.

Glass is a known substance that is substantially rigid in shape and when stacked or exposed to external stresses does not readily deform.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is an illustration of a cross-sectional view of glass layer with a plurality of through glass vias.

FIG. 2 is an illustration of an example of a cross sectional view of a glass layer.

FIGS. 3A-3F are illustrations of cross sectional views of an example of a process of forming a glass core.

FIG. 4 is an illustration of a cross sectional view of a glass layer.

FIG. 5 is an illustration of a glass layer on a substrate.

FIG. 6 is an illustration of a system level diagram, depicting an example of an electronic system.

### DETAILED DESCRIPTION

Some substrates for computer chips or other electrical systems can be built, formed or otherwise assembled from layers of materials, for example resins, polymers, glass or the like. A resin layer can be made from a polymer resin. The resin layer can also have fiberglass dispersed throughout. The foundation of these layers can be a core layer on which other layers made from the same or similar materials, or other components of a chip can be coupled, built up, or assembled.

A resin core can have layers of a dielectric material coupled to upper or lower surfaces of the resin core. The resin core can also have a conductive material coupled to the surfaces, such as a copper layer or copper foil. However, any conductive material suitable for the purpose may be used. Though holes can be formed through the resin core. Further, layers can be coupled to the resin core to form stacked layers with electrically conductive interconnects applied, coupled or formed on or to the surfaces of the layers.

Resin as a layer material and dielectric materials coupled to the resin layers, in some situations, can be a deformable material. Polymers in the resin layers or in the dielectric material can deform when subjected to applied pressures or when the material is subjected to fluctuations in temperature. Deformation to resin layers and dielectric materials can be expansion or contraction of the material in lateral directions. Deformation can also be due to compression or expansion in a depth direction. The deformation can also be undulations, ripples or uneven thicknesses in the resin core material.

Both applied pressures and temperature fluctuations are known environmental conditions during manufacturing of computer chips which can result in changes in dimensions of at least one resin layer or dielectric material layer. Deformations can result in changes in the location of the components coupled to or formed in or with at least one resin layer.

The present inventors have recognized a need for layers within a substrate, core or computer chip which can be a solid (e.g., nondeformable, fixed, rigid or the like) structure which, when subjected to changes in environmental conditions and does not experience significant changes to material properties. The present inventors have recognized the need for a material for layers which can remain substantially constant so any components, such as additional layers, though holes or conductive materials can remain substantially in place.

An example of a material which can be used to form solid (e.g., nondeformable, fixed, stable or the like) structure for a layer can be glass, or a glass-like material. Other glass layers or other material layers can be stacked on the glass layer. The glass layer can be a central core for a substrate or chip, or the glass layer can be an individual core which is not central, but instead at a different location within the layers of the substrate or chip.

Glass is generally known to be a material which is rigid. Glass can also be a material which is not easily deformed when subjected to changes in environmental conditions. For example, when glass is exposed to pressures it does not easily change in structure or form. When glass is exposed to pressures it usually does not deform such as be compressed or expanded in thickness, or a depth direction. Glass also does not easily expand in a lateral or longitudinal direction when subjected to pressure or stresses are applied to the surface.

Glass can be a material which is known to have flat, even or level surfaces. Both sides of a glass surface (e.g., upper and lower or opposing sides if oriented in a different configuration) can be substantially flat or just one side of a sheet or piece of glass can be substantially flat while the other side can have ripples, undulations or other irregularities in the surface texture. When using glass, or a similar material, for a layer having a flat, even or level surface (i.e., a surface without ripples, undulations, protrusions, indentations or the like) can be beneficial for accurate placement of through holes, through glass vias (TGV), electrically conductive interconnects or any other component which may be desired or necessary.

Glass is a material which has a known thermal and mechanical stability. Glass can be considered as a next generation substrate material which can assist in achieving approximately true position and minimize thickness variation during, for example, a layering process flow.

The thermal mechanical benefits of glass materials can be a benefit to glass which can be layered. Such thermal mechanical benefits can minimize undulations which can occur when layers are compressed or stacked on previous layers. In other words, the thermal mechanical qualities of glass can result in the glass retaining substantially an original shape or dimensions. The thermal and mechanical quantities of glass can also result in minimization of the occurrence of shrinkage when further layers are stacked. The thermal mechanical qualities of glass can also be beneficial when adding conductive materials, such as copper, to the surface of the glass.

The glass layer can include a silicate-based glass (e.g., lithium-silicate, borosilicate, aluminum silicate, etc.). In variations, the glass of the glass layer can be a lower quality glass (e.g., glass made with soda lime), or a higher quality glass (e.g., glass made with fused silica). Glass can be a material with low conductivity and one which can minimize migration of conductive materials across surfaces or within the core material. Conductive materials, such as copper, during manufacturing of the core, or chip, can migrate across surfaces and damage or coat other components of the core or chip. When migration occurs, affected components are known in some instances to not function efficiently or effectively.

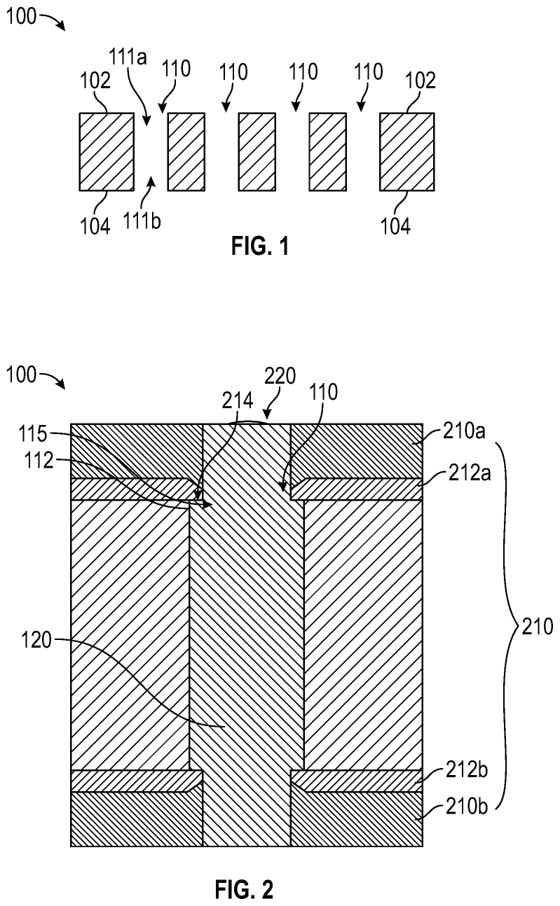

In an example a glass layer 100 with preformed through holes 110, electrically conductive interconnects or TGVs (hereinafter “TGV”) is illustrated in FIG. 1. TGV can refer to one through hole or a plurality of through holes in the glass layer 100. Glass layer 100 can refer to as the base or foundation on which further layers (glass or other materials used in a substrate or a chip) can be stacked, laminated, adhered or other components can be adhered, coupled, attached or the like. The glass layer 100, as illustrated, can have at least one TGV 110 or a plurality of TGVs 110. The glass layer 100 can be prepatterned with a predetermined number of TGVs 110 extending from a first surface 102 to a second surface 104, with a corresponding first opening 111a and second opening 111b. Each of the first opening 111a and second opening 111b can have a corresponding perimeter 112 or edge that extends around, for example in a substantially circular profile. The TGV 110 can be a component of the mounting structure or scheme.

As illustrated in FIG. 2, the glass layer 100 can support least one electrically conductive interconnect 115, lead or the like (hereinafter “interconnect”). The electrically conductive interconnect 115 can include the TGV 110 and can have an interior of the TGV 110 be filled or plated with, for example, copper plating, gold plating, a metallic conductor plug or any plating, plug or the like as dictated by the purpose (hereinafter “metallic conductor plug”). The at least one metallic conductor plug 120 can be formed from copper, aluminum, gold, or any other material which can provide a pathway to transmit an electrical signal. The at least one metallic conductor plug 120 can refer to a copper trace, copper pad or any interconnect or pad formed from any conductive material suitable for the purpose of the core, substrate or glass layer 100. The metallic conductor plug 120 can extend at least partially within at least one TGV 110. As illustrated in FIG. 2, at least one TGV 110 can be formed at any location on or in the glass layer 100 which is suitable for the purpose of the glass layer 100.

In an example of a glass layer 100, a buffer layer 210 can be laminated, disposed on, adhered to, or otherwise coupled with at least one of the first surface 102 or the second surface 104. The buffer layer 210 can be a dielectric material, such as Ajinomoto Build-Up Film®, or a similar material. The buffer layer 210 can extend into an edge region 214 of the TGV 110 in a manner that the buffer layer 210 overhangs, extends, protrudes, or the like the perimeter of the TGV 110. The edge region 214 can correspond to the area extending beyond the perimeter 112 of the TGV 110 and towards the center of the TGV 110. The edge region 214 can correspond to the area of the buffer layer 210 where the buffer layer 210 extends from the perimeter 112 of the TGV 110 to an opening in the buffer layer 210 corresponding to the TGV 110. In an example, the buffer layer 210 can abut the metallic conductor plug 120 in an area corresponding to the edge region 214.

The buffer layer 210 can be sandwiched between a subsequent glass layers. The glass layer 100 can have electrically conductive interconnects 115 disposed, or placed, on the first surface 102 of the glass layer 100 or extending through or to the second surface 104 of the buffer layer 210 that can be connected, or coupled with, the subsequent layer glass core.

In an example, the buffer layer 210a is affixed, connected or coupled with the first surface 102 of the glass layer 100 with a silicon nitride or other adhesion promotor material layer 212a. Similarly, the second surface 104 of the glass layer 100 can be similarly affixed, connected or coupled with a second buffer layer 210b through the use of a second adhesion promotor material layer 212b. While silicon nitride can be used to affix, connect or couple the buffer layer 210 with the glass layer 100 with any material suitable for the purpose can be used.

The adhesion promotor material layer 212a, 212b can be formed or otherwise coupled with the glass layer 100 in a manner that at least a portion of the adhesion promotor material layer 212a, 212b has an edge region 214 that extends over the perimeter 112 or the edge of the TGV 110. In an example, the edge region 214 is substantially coplanar with the first surface 102 of the glass layer 100. The edge region 214 can include a lip, overhang, protrusion, extension or the like which extends from or over a perimeter of the first opening and the second opening towards a central region of the metallic conductor plug 120 or TGV 110. In an example, the first surface 102 is a top surface and the second surface 104 is a bottom surface of the glass layer 100. The edge region 214 can be coplanar with at least one of the top surface and/or the bottom surface. The edge region 214 can be substantially flat or level with the first surface 102 or the second surface 104 when viewed from a cross-section of the glass layer 100.

The edge region 214 being coplanar with at least one of the first surface 102 or second surface 104 can promote uniformity between the plurality of TGVs 110 and the metallic conductor plug 120 extending through the TGVs 110. The edge region 214 can promote consistency in location of the TGV 110 when drilling in the region of the TGV 110.

The buffer layer 210 can be an intermediary between subsequent layers, either of glass or another material, as the design dictates. The metallic conductor plug 120 can be formed to extend within a through hole 220 in the buffer layer 210. The electrically conductive interconnect 115 can be a conduit between subsequent layers that are stacked or otherwise connected with the glass layer 100.

A single glass layer 100 or a plurality of layers can be a component of an electrical system. In an example, the single glass layer 100 or plurality of layers including the glass layer 100 can be coupled with a die, substrate or package. The single glass layer 100 or plurality of layers including the glass layer 100 can be a component of a circuit.

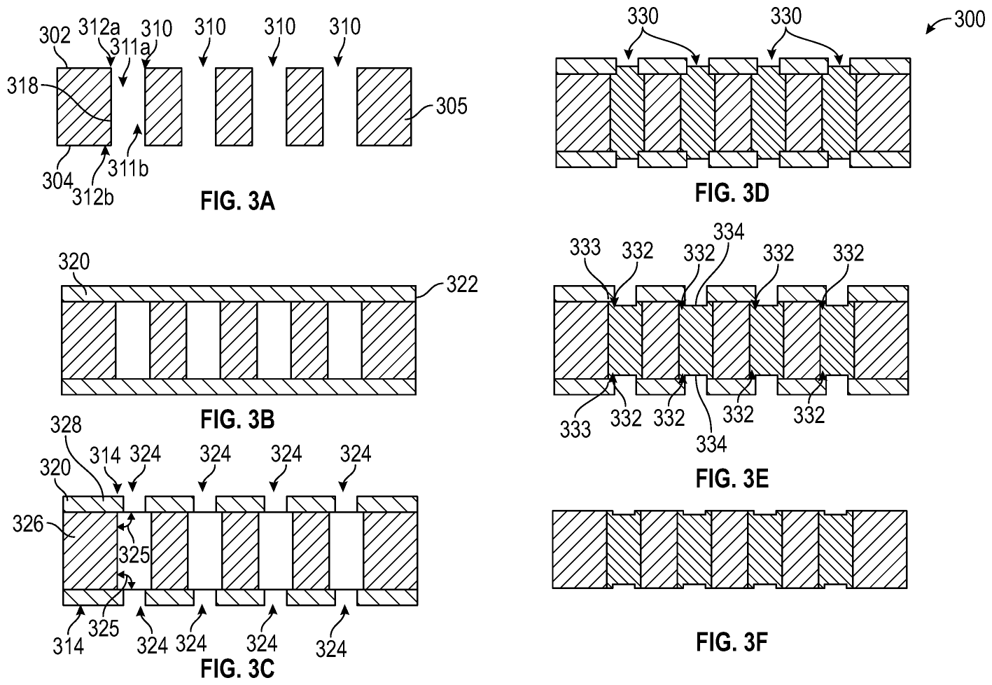

In an example method of forming a glass layer 300, a prepatterned glass layer 305 is provided with a plurality of through holes, or through glass vias (TGVs) 310, as illustrated in FIG. 3A. Each of the plurality of TGVs 310 can have a corresponding first opening 311a and a second opening 311b on an opposing side in a depth direction of each of the plurality of TGV 310. Each of the first openings 311a and second openings 311b can have a corresponding perimeter 312a, 312b which extends around the opening in any shape configured for the purpose. The plurality of TGVs 310 can extend from a first surface 302 to an opposing second surface 304. The plurality of TGVs 310 can each extend at the same angle through the prepatterned glass layer 305. The plurality of TGVs can also extend at different angles through the prepatterned glass layer 305. In an example the TGVs 310 can extend substantially perpendicular to the first surface 302 and the second surface 304.

As illustrated in FIG. 3B, a seed layer 322 can be applied to at least the first surface 302 and/or the second surface 304. In an example, at least a portion of the first surface 302 and the second surface 304 can have the seed layer 322. In another example, the whole surface of the first surface 302 and the second surface 304 will have the seed layer 322. The seed layer 322 can be an electrically conductive material. For example, the seed layer 322 can be a layer of platinum, titanium, copper, aluminum or aluminum alloys, magnesium or the like deposited, laminated or otherwise placed on the first surface 302 and the second surface 304. The seed layer 322 can be an electrically conductive material to allow provide a surface for copper in elytic copper plating to form copper. The seed layer 322 can assist in preventing copper from creeping or spreading on exposed surfaces, such as the first surface 302 or the second surface 304 when a copper layer is deposited in the TGV (as discussed further, below).

A dry film photoresist (DFR) 320 can be laminated, placed, adhered, coupled or the like (hereinafter “laminate”) over the seed layer 322. The DFR 320 can be used to transfer images or other indicators which locate the TGVs 310. For example, the DFR is laminated using a hot roller that passes over the first surface 302 and the second surface 304. The DFR 320 can also be sued to define where to plate copper as the DFR 320 can block, prevent or inhibit a copper plating solution from the contacting the area covered by the DFR 320. As the hot roller passes over the designated surface, the hot roller laminates the DFR 320 on the surface 302, 304 with indicators for the location of the TGVs 310. In an example, the DFR 320 is tented over the TGVs 310, or it is laminated over the TGVs 310 in a manner where the DFR 320 does not, or minimally, cave or collapse into the TGV 310. The DFR 320 can be engineered to enhance tenting performance and elongation to avoid caving or collapsing into the TGV.

The DFR 320 can also be laminated using a wet DFR process. When wet DFR is used, the interior, cavity, passage or the like, of TGV 310 can be filled with a fluid to prevent the DFR 320 from collapsing or caving into the TGV 310. The TGV 310 can be filled with a fluid such as an electroless or deionized water, or any fluid which will not react with the DFR 320. The fluid filled into the DFR 320 can act as a support for the DFR 320 during the lamination process or an impediment against the DFR to prevent the DFR 320 from collapsing or caving into the TGV 310. The fluid can then be released from within the TGV 310 when openings are formed in the DFR 320 corresponding to the TGV 310.

In an example, when the DFR 320 is laminated on the first surface 302 and the second surface 304, a high accuracy lithographic tool can be used to form indicators on or in the DFR 320 to assist in locating the TGVs 310 and removing the DFR 320 from an area corresponding to at least the first opening 311a or the second opening 311b of the TGV 310. In an example, the overlay DFR 320 can have less than 5 μm distortion or deviation from the location of the TGVs 310. The indicators patterned on the DFR 320 can be smaller than the dimensions of the TGVs 310. For example, the profile of the TGV 310 is a circle, or cylinder in a three-dimensional form, the indicator patterned on the DFR 320 is a circle having a diameter smaller than the diameter of the circle or profile of the TGV.

As illustrated in FIG. 3C, openings 324 can be formed in the DFR 320 that are smaller than the TGV. The openings 324 can correlate to the central region of the TGV and one side of the DFR 320 can be spaced from an opposing side of the DFR 320 on an opposite lateral portion of the TGV 310. The openings 324 can be formed in the DFR 320 by exposure and development. The openings 324 can also be formed in any other means suitable for the designated purpose. The opening 324 in the DFR 320 can be smaller in profile, shape or diameter than the profile, shape or diameter of the TGV 310. The DFR 320 opening can be smaller than TGV 310 to allow the patterning needs to account for a possible overlay error. Since there can be an error when performing lithography patterning, that can cause the DFR 320 opening position to deviate from opening 324. In an example, having the DFR 320 opening be smaller can assist in ensuring the DFR opening is always on TGV opening range. The smaller opening 324 than the TGV 310 can result in a lip 328, protrusion, projection, extension or overhang (hereinafter “lip”) being formed with the DFR 320 over at least a portion of the TGV 310. An underside portion 326 of the DFR 320 can be in contact with the seed layer 322. The underside portion 326 can be approximately planar with, or approximately perpendicular to, the first surface 302 and the second surface 304. The underside portion 326 can be the portion of the lip 328 that is exposed to the TGV 310. In an example, the angle 325 between the underside portion 326 of the lip 328 and a wall 318 of the TGV 310 can be approximately 90°. In another example, the angle 325 can be an obtuse angle or the angle 325 can be an acute angle.

The lip 328 can extend into an edge region 314 of the TGV 310 in a manner that the lip 328 overhangs, extends, protrudes, or the like the perimeter of the TGV 310. The edge region 314 can correspond to the area extending beyond the perimeter 312a, 312b of the TGV 310 and towards the center of the TGV 310. The edge region 314 can correspond to the area of the DFR 320 where the DFR 320 extends from the perimeter 312a, 312b of the TGV 310 to an opening in the DFR 320 corresponding to the TGV 310.

As illustrated in FIG. 3D, the interior, cavity or passageway of the TGV 310 can be filled or plated with copper 330, or any material suitable for the purpose, such as gold, aluminum or aluminum alloys. The copper 330 can be plated or filled beyond the opening of the TGV 310. In another example, the DFR 320 is a predetermined thickness which can assist in preventing copper 330 from extending past an exposed surface of the DFR. In another example, the copper 330 can extend past the exposed surface of the DFR, as the copper 330 can be etched or removed at a later point, as will be discussed later. In an example, the copper 330 can be plated or filled to extend into the depth of the lip 328. As illustrated in FIG. 3D, the copper 330 can be plated or filled in a manner that at least a portion of the copper 330 approximately matches or corresponds to the profile or shape of the lip 328 including the angle 325. For example, the TGV 310 can be plated with copper up to the DFR 320 or into the opening 324 in the DFR 320.

Retaining the DFR 320 on the first surface 302 and the second surface 304, there can be minimal copper which is plated to the first surface 302 and second surface 304. Experimental data has indicated retaining the DFR 320 on the first surface 302 and second surface 304 can result in more uniformity of plating copper within the TGV 310 both during filling or plating and during etching or removal. Retaining the DFR 320 on the first surface 302 and second surface 304 can also lead to better process control. For example, the openings 324 can assist in preventing misalignment of the copper 330 when plating or filling in the TGV 310. If misalignment does occur, the risk to damage to the glass layer 300 can be minimal. For example, the impact from misalignment can be during the microvia drilling in a buffer layer above the TGV 310.

In an example as illustrated in FIG. 3E, the copper 330 that extends beyond the prepatterned glass layer 305 and into the opening 324 can be etched back. The copper 330 can be etched back or removed by any similar method suitable for the purpose, while the DFR 320 can remain laminated or the like, during the etching process. With the DFR 320 remaining laminated during and after etching, at least an end portion 332 of the copper 330 which has been plated or filled in the TGV 310 can remain under the lip 328 of the DFR 320. In an example, after etching, the profile of the end portion 332 of the copper 330 can have a recessed portion 334, or indented portion. In an example, the end portion 332 can protrude or extend around the recessed portion 334. An end surface 333 of the end portion 332 can protrude or extend a predetermined distance towards the DFR 320 and away from the recessed portion 334. In an example, the end portion 332 can form a ring that flush with the first surface 302 or the second surface 304. The ring of the end portion 332 can circumnavigate the interior of the TGV 310. The recessed portion 334 can have an approximately 90° angle within the recessed portion with respect to the end portion 332, and when viewed from a cross-section through the prepatterned glass layer 305.

As illustrated in FIG. 3F, after the copper 330 has been etched or otherwise removed, the DFR 320 can be stripped from the upper surface 302 and the lower surface 304. The DFR 320 can be at least partially stripped or otherwise removed from the upper surface 302 and lower surface 304 or completely stripped. The prepatterned glass layer 305 with the copper 330 that has been etched can have a profile with the end surface 333 of the copper 330 substantially coplanar with the upper surface 302 and the lower surface 304. In an example, the recessed portion 334 can be recessed from or indented from the upper surface 302 and the lower surface 304.

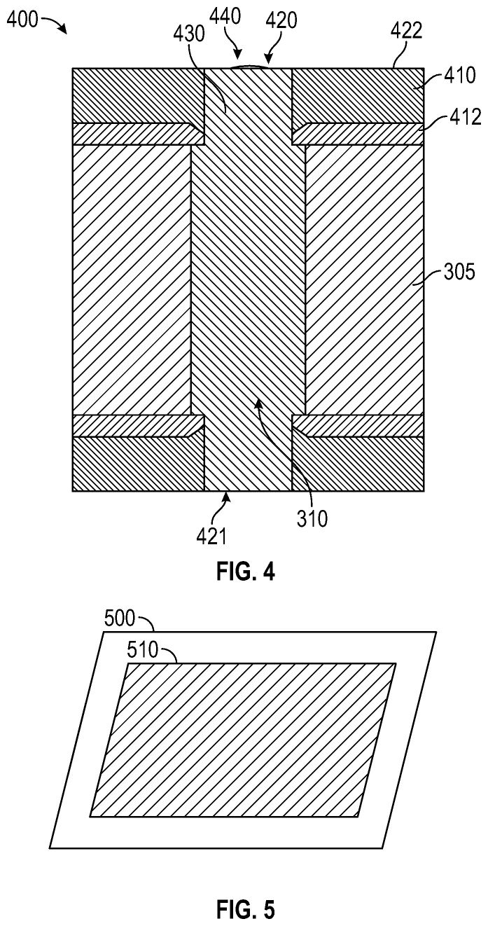

After the DFR 320 is stripped from the first surface 302 and second surface 304, further layers can be coupled, attached or otherwise placed on the prepatterned glass layer 305. For example, and as illustrated in FIG. 4, a buffer layer 410 can be placed on at least one of the first surface 302 and second surface 304. This buffer layer 410 can be a dielectric material, a foam or any other material suitable for the purpose. The buffer layer 410 can be coupled or attached to the first surface 302 or second surface 304 with an adhesive layer 412. The adhesive layer 412 can be a silicon nitride or any other material suitable for coupling the buffer layer 410 to the prepatterned glass layer 305.

In an example, the adhesive layer 412 can be deposited on the first surface 302 and second surface 304 as well as on the end portion 332 of the copper. The end portion 332 can be coplanar with the corresponding first surface 302 or second surface 304. The adhesive layer 412 can then extend continuously from the first surface 302 or second surface 304 to the end portion 332 without any interruptions or breaks. The buffer layer 410 can be coupled or adhered to the first surface 302 or the second surface 304 with the adhesive layer 412 as an intermediary. The buffer layer 410 can extend at least partially over at least the first surface 302 and second surface 304.

The buffer layer 410 can have a through hole 420 formed to extend from an upper surface 422 through the adhesive layer 412. The through hole 420 can correspond with the TGV 310 and the copper 330 filled or plated inside. The through hole 420 can have a size or profile smaller than the size or profile of the TGV 310. For example, the through hole 420 can be sized to be similar to the dimensions of the openings 324 that was formed in the DFR 320. The through hole 420 can be sized to be similar to the recessed portion 334 of the copper 330.

In an example, the through hole 420 can provide an opening for additional copper 430 to be filled in the through hole 420. The additional copper 430 can be filled or plated to extend within the through hole 420 from the recessed portion 334 to the upper surface 422 of the buffer layer 410.

The pathway formed within the through hole 420 extending through the TGV 310 and, optionally, an opposing through hole 421, can be an electrical interconnect 440. The electrical interconnect 440 can be a pathway for the transmission electrical signals. For example, a glass layer 400 including the prepatterned glass layer 305, an adhesion layer 412 and the buffer layer 410 and having the electrical interconnect 440 pass through can be one layer of a stack of layers of similar or different materials.

As illustrated in FIG. 5, the glass layer 510 can be a component of an electrical system such as a die, package or coupled to a substrate 500. Additional components can be coupled to the glass layer 510 as dictated by the purpose. For example, active components such as transistors can be coupled to glass layer 400. In another example, passive components such as resistors, transformers, and diodes can be coupled with the glass layer 510.

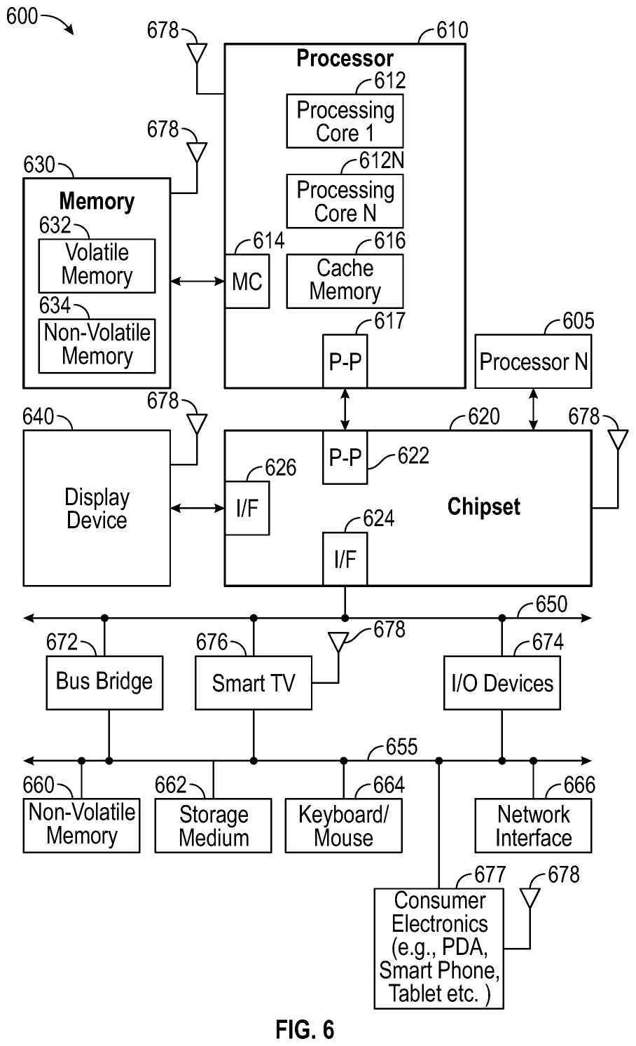

FIG. 6 illustrates a system level diagram, depicting an example of an electronic device (e.g., system) that may include an electronic system, for example, from any of the example process flows described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

### Various Notes and Aspects

Aspect 1 can include an electronic device that can include at least one layer formed from glass, a plurality of through glass vias formed within the at least one layer, and a metallic conductor plug filling an interior of the plurality of through glass vias, the metallic conductor plug including an exposed surface, the exposed surface including. The through glass vias can include a perimeter corresponding to a first opening on a first surface of the glass layer and an edge corresponding to a second opening on a second, opposing, surface of the glass layer. The metallic conductor plug can include a central region and an edge region, wherein the edge is substantially coplanar with at least one of a top surface or a bottom surface of the at least one layer.

Aspect 2 can include, or can optionally be combined with the subject matter of Aspect 1, to optionally include a buffer layer coupled to at least one of the first surface and the second, opposing, surface, where the buffer layer extends beyond the perimeter of the through glass via and a through hole extending through the buffer layer from the first surface towards the second surface.

Aspect 3 can include, or can optionally be combined with the subject matter of Aspect 1 or Aspect 2, to optionally include an angle formed between a wall of the through glass via and the buffer layer extending is approximately perpendicular. Aspect 4 can include, or can optionally be combined with the subject matter of Aspects 1-3, to optionally include the metallic conductor plug abuts a buffer layer at the edge region.

Aspect 5 can include, or can optionally be combined with the subject matter of Aspects 1-4, to optionally include a buffer layer coupled with the top surface of the at least one layer and a bottom surface of the at least one layer.

Aspect 6 can include, or can optionally be combined with the subject matter of Aspects 1-5, to optionally include the buffer layer extends over the edge region.

Aspect 7 can include, or can optionally be combined with the subject matter of Aspects 1-6, to optionally include an adhesion promoter deposited on the top surface of the at least one layer and a buffer layer deposited on top of the adhesion promoter.

Aspect 8 can include an electronic system comprising a die and a substrate. The substrate can be coupled to the die and includes a prepatterned glass layer comprising a first exposed surface and a second exposed surface, a plurality of through holes formed within the prepatterned glass layer, each of the plurality of through holes has a first end and a second end and a layer of copper plating extending within each through hole of the plurality of through holes, the copper plating including a first copper plating surface corresponding with the first end and a second copper plating surface corresponding with the second end. The first copper plating surface includes a ring flush with the first exposed surface and circumnavigating an interior of each of the plurality of through holes. The second copper plating surface includes a ring flush with the second exposed surface and circumnavigating the interior of each of the plurality of through holes.

Aspect 9 can include, or can optionally be combined with the subject matter of Aspect 8, to optionally include an adhesion promotor coupled with the first exposed surface and the second exposed surface and a buffer layer coupled with an exposed surface of the adhesion promotor.

Aspect 10 can include, or can optionally be combined with the subject matter of Aspect 8 or Aspect 9, to optionally include the buffer layer is a dielectric material.

Aspect 11 can include, or can optionally be combined with the subject matter of Aspects 8-10, to optionally include a first seed layer coupled between the first exposed surface and a first dry film photoresist layer and a second seed layer coupled between the second exposed surface and a second dry film photoresist layer.

Aspect 12 can include, or can optionally be combined with the subject matter of Aspects 8-11, to optionally include the dry film photoresist has elongation and mechanical properties to avoid collapsing into at least one of the plurality of through holes.

Aspect 13 can include, or can optionally be combined with the subject matter of Aspects 8-12, to optionally include a first dry film photoresist layer extends over the ring of the first copper plating surface and a second dry film photoresist layer extends over the ring of the second copper plating surface.

Aspect 14 can include, or can optionally be combined with the subject matter of Aspects 8-13, to optionally include the dry film photoresist extends beyond the ring indicates misalignment of the dry film photoresist.

Aspect 15 can include, or can optionally be combined with the subject matter of Aspects 8-14, to optionally include a buffer layer extends over the ring of the first copper plating surface and a buffer layer extends over the ring of the second copper plating surface.

Aspect 16 can include method of forming a layer for an electrical system comprising forming a plurality of through glass vias in a glass layer, the each of the plurality of through glass vias having a first opening and an opposing second opening. Fixing a first seed layer to a first surface of the glass layer and fixing a second seed layer to a second surface of the glass layer. The second surface of the glass layer opposes the first surface of the glass layer. Laminating dry film photoresist over the seed layer on the first surface and the second surface. Removing the dry film photoresist and seed layer from an area corresponding to the first opening and opposing second opening of the plurality of through glass vias.

Depositing copper plating in each through glass via of the plurality of through glass vias. Removing the dry film photoresist and seed layer from the first surface and the second surface.

Aspect 17 can include, or can optionally be combined with the subject matter of Aspect 16, to optionally include filling the plurality of through glass vias with deionized water before laminating the dry film photoresist.

Aspect 18 can include, or can optionally be combined with the subject matter of Aspect 16 or Aspect 17, to optionally applying a first buffer layer to the first surface of the glass layer and applying a second buffer layer to the second surface of the glass layer.

Aspect 19 can include, or can optionally be combined with the subject matter of Aspects 16-18, to optionally include removing the dry film photoresist from an area corresponding to the first opening and from an area corresponding to the second opening. The dry film photoresist forms a lip extending from a perimeter of the first opening and a lip extending from a perimeter of the second opening.

Aspect 20 can include, or can optionally be combined with the subject matter of Aspects 16-19, to optionally include affixing an adhesion promoter to the first surface and to the second, opposing surface. Coupling a first buffer layer on the adhesion promoter on the first surface. Coupling a second buffer layer on the adhesion promoter on the second, opposing surface. The adhesion promoter and the first buffer layer forms a first lip extending from a perimeter of the first opening. The adhesion promoter and the second buffer layer forms a second lip extending from a perimeter of the second opening. The copper plating forms a flat surface against the adhesion promoter and the first buffer layer and the second buffer layer.

Each of these non-limiting aspects can stand on its own, or can be combined in various permutations or combinations with one or more of the other aspects.

The above description includes references to the accompanying drawings, which form a part of the detailed description. The drawings show, by way of illustration, specific embodiments in which the invention can be practiced. These embodiments are also referred to herein as “aspects” or “examples.” Such aspects or example can include elements in addition to those shown or described. However, the present inventors also contemplate aspects or examples in which only those elements shown or described are provided. Moreover, the present inventors also contemplate aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as aspects, examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. An electronic device comprising:
at least one layer formed from glass;
a plurality of through glass vias formed within the at least one layer;
wherein each of the through glass vias has a perimeter corresponding to a first opening on a first surface of the glass layer and an edge corresponding to a second opening on a second, opposing, surface of the glass layer; and
a metallic conductor plug filling an interior of the plurality of through glass vias, the metallic conductor plug including an exposed surface, the exposed surface including:
a central region; and
an edge region, wherein the edge is substantially coplanar with at least one of a top surface or a bottom surface of the at least one layer.

2. The electronic device of claim 1, further comprising:
a buffer layer coupled to at least one of the first surface and the second, opposing, surface; and
wherein the buffer layer extends beyond the perimeter of the through glass via;
a through hole extending through the buffer layer from the first surface towards the second surface.

3. The electronic device of claim 2, wherein an angle formed between a wall of the through glass via and the buffer layer extending is approximately perpendicular.

4. The electronic device of claim 1, wherein the metallic conductor plug abuts a buffer layer at the edge region.

5. The electronic device of claim 1, further comprising:
a buffer layer coupled with the top surface of the at least one layer and a bottom surface of the at least one layer.

6. The electronic device of claim 5 wherein the buffer layer extends over the edge region.

7. The electronic device of claim 1 further comprising:
an adhesion promoter deposited on the top surface of the at least one layer; and
a buffer layer deposited on top of the adhesion promoter.

8. An electronic system comprising:
a die;
a substrate coupled to the die comprising;
a prepatterned glass layer, the prepatterned glass layer comprising:
a first exposed surface and a second exposed surface;
a plurality of through holes formed within the prepatterned glass layer, each of the plurality of through holes has a first end and a second end; and
a layer of copper plating extending within each through hole of the plurality of through holes, the copper plating including a first copper plating surface corresponding with the first end and a second copper plating surface corresponding with the second end;
wherein the first copper plating surface includes a ring flush with the first exposed surface and circumnavigating an interior of each of the plurality of through holes;
wherein the second copper plating surface includes a ring flush with the second exposed surface and circumnavigating the interior of each of the plurality of through holes.

9. The electronic system of claim 8, further comprising:
an adhesion promotor coupled with the first exposed surface and the second exposed surface; and
a buffer layer coupled with an exposed surface of the adhesion promotor.

10. The electronic system of claim 9, wherein the buffer layer is a dielectric material.

11. The electronic system of claim 8, further comprising:
a first seed layer coupled between the first exposed surface and a first dry film photoresist layer; and
a second seed layer coupled between the second exposed surface and a second dry film photoresist layer.

12. The electronic system of claim 11, wherein the dry film photoresist has elongation and mechanical properties to avoid collapsing into at least one of the plurality of through holes.

13. The electronic system of claim 8, further comprising:
a first dry film photoresist layer extends over the ring of the first copper plating surface; and
a second dry film photoresist layer extends over the ring of the second copper plating surface.

14. The electronic system of claim 13, wherein the dry film photoresist extends beyond the ring indicates misalignment of the dry film photoresist.

15. The electronic system of claim 8, further comprising:
a buffer layer extends over the ring of the first copper plating surface; and
a buffer layer extends over the ring of the second copper plating surface.

16. A method of forming a layer for an electrical system comprising:
forming a plurality of through glass vias in a glass layer, the each of the plurality of through glass vias having a first opening and an opposing second opening;
fixing a first seed layer to a first surface of the glass layer and fixing a second seed layer to a second surface of the glass layer;
wherein the second surface of the glass layer opposes the first surface of the glass layer;
laminating dry film photoresist over the seed layer on the first surface and the second surface;
removing the dry film photoresist and seed layer from an area corresponding to the first opening and opposing second opening of the plurality of through glass vias;
depositing copper plating in each through glass via of the plurality of through glass vias; and
removing the dry film photoresist and seed layer from the first surface and the second surface.

17. The method of forming the layer of claim 16, further comprising:
filling the plurality of through glass vias with deionized water before laminating the dry film photoresist.

18. The method of forming the layer of claim 16, further comprising:
applying a first buffer layer to the first surface of the glass layer; and
applying a second buffer layer to the second surface of the glass layer.

19. The method of forming the layer of claim 16, further comprising:
removing the dry film photoresist from an area corresponding to the first opening and from an area corresponding to the second opening;
wherein the dry film photoresist forms a lip extending from a perimeter of the first opening and a lip extending from a perimeter of the second opening.

20. The method of forming the layer of claim 16 further comprising:
affixing an adhesion promoter to the first surface and to the second, opposing surface;
coupling a first buffer layer on the adhesion promoter on the first surface; and
coupling a second buffer layer on the adhesion promoter on the second, opposing surface;
wherein the adhesion promoter and the first buffer layer forms a first lip extending from a perimeter of the first opening;
wherein the adhesion promoter and the second buffer layer forms a second lip extending from a perimeter of the second opening;
wherein the copper plating forms a flat surface against the adhesion promoter and the first buffer layer and the second buffer layer.
